(19) United States
(12) Patent Application Publication
(10) Pub. No.: US 2008/0012103 A1
(43) Pub. Date: Jan. 17, 2008

(54) EMI ABSORBING GAP FILLING MATERIAL

(76) Inventors: Robert H. Foster, Westford, MA (US); Michael H. Bunyan, Chelmsford, MA (US)

Correspondence Address: RISSMAN JOBSE HENDRICKS & OLIVERIO, LLP, ONE STATE STREET, SUITE 800, BOSTON, MA, 02109, US

(21) Appl. No.: 11/777,462

(22) Filed: Jul. 13, 2007

Related U.S. Application Data
(60) Provisional application No. 60/807,216, filed on Jul. 13, 2006.

(51) Int. Cl. H01L 23/495

(52) U.S. Cl. 257/675

(57) ABSTRACT

A thermally conductive gap filling material for the absorption of electromagnetic (EM) radiation emitted from an electronic device is provided. The gap filling material facilitates conduction of excessive heat generated by the electronic device to a heat dissipater. The heat dissipater further dissipates the excessive heat to the surrounding environment. The gap filling material comprises a binder material and magnetic filler. The magnetic filler is dispersed in binder material. The magnetic filler absorbs EM radiation and causes the gap filling material to be thermally conductive.

### CROSS-REFERENCE TO RELATED APPLICATIONS

This application claims the benefit of priority of U.S. Provisional Application No. 60/807,216, filed on Jul. 13, 2006, the disclosure of which is incorporated herein by reference thereto in its entirety.

### BACKGROUND OF THE INVENTION

The present invention relates to a gap filling material for the thermal conduction of heat generated by electronic devices. More particularly, the present invention relates to a gap filling material for the absorption of electromagnetic (EM) radiation emitted by electronic devices, and methods for providing the same.

Generally, all electronic components generate heat when in operation. The excessive heat generated from the electronic components of such devices causes an increase in the temperature of the electronic components. Temperature is among the important parameters controlling the performance and operation of nearly all semiconductor electronic devices and other electronic components. A rise in temperature adversely affects performance, operation, and efficiency of electronic devices. Thus, to keep the electronic devices functioning in a normal way and to avoid any damage to the electronic devices, it is necessary to remove excessive heat from the electronic devices, such that the temperature of the electronic components can be kept within safe limits.

Conventionally, various methods have been used to dissipate the excessive heat generated by electronic components. One of these methods is to place a heat sink onto the electronic component or device. The excessive heat generated by the electronic component or device is absorbed by the heat sink. The heat sink ultimately releases the excessive heat to the surroundings. A thermally conductive material is placed at the interface of the heat sink and the electronic component or device thereby increasing the thermal conduction across the interface.

Further, in general, electronic components are sources of electromagnetic (EM) radiation. Electronic components, for example, transmitters, transceivers, microcontrollers, microprocessors and the like radiate a portion of the electric signals propagating through the circuit as EM radiation. The EM radiation generated in this way is referred to as EM noise. Higher operating frequency ranges of the electronic components leads to the EM noise that primarily comprise radio frequency (RF) radiations. These RF radiations are normally referred to as RF noise. As used herein, EM noise and RF noise are used merely to refer to EM radiations emitted from an electronic device. Moreover, EM noise and RF noise, unless otherwise stated, are used interchangeably throughout the specification. EM radiation may also be emitted from a nearby electronic device.

In general, commercial electronics such as LCDs, TFTs, Plasma displays, laptops, high speed personal computers, video game consoles, mobile phones, and the like are sources of EM noise. The EM noise or RF noise may interfere with nearby electronic devices. The EM noise induces unwanted electric signals in the circuitry of nearby electronic devices. Consequently, EM noise may interrupt, obstruct, degrade, and limit the effective performance and operation of nearby electronic devices.

Conventionally, electronic devices have been shielded to impede the emission of EM noise. Specifically, the electronic devices can be enclosed in a shield. The shield may be made of various materials, for example, metal sheets, plastic composites, conductive polymer sprays, metal filled epoxy pastes and the like. The shield absorbs EM radiation thereby impeding the emission of EM noise from an assembly of the electronic devices and the shield. However, conventional shields typically perform poorly when it comes to absorbing excessive heat generated from electronic devices. Further, if thermally conductive materials, such as thermally conductive gap filling materials, are used to facilitate the conduction of heat generated by the electronic devices, these thermally conductive materials perform poorly in absorbing EM noise emitted from the electronic devices.

Therefore, for an electronic device generating excessive heat and emitting EM noise, there is a need for a material that can remove the excessive heat and can also provide a shield to impede the emission of EM noise from the electronic device.

### SUMMARY OF THE INVENTION

According to an aspect of the present invention, a gap filling material for the absorption of electromagnetic (EM) radiation comprises a binder material and one or more magnetic filler materials. The one or more magnetic filler materials are dispersed in the binder material. The gap filling material primarily absorbs radio frequency (RF) radiation. According to various aspects of the present invention, the gap filling material may have various forms such as a grease, a sheet, an adhesive, a film, a tape and the like.

### BRIEF DESCRIPTION OF THE DRAWINGS

The foregoing and other advantages and features of the invention will become apparent upon reading the following detailed description and upon reference to the drawings in which:

FIG. 1 illustrates an assembly comprising a gap filling material according to various embodiments of the present invention;

FIG. 2 illustrates an assembly comprising a metal sub-chassis and a microprocessor according to various embodiments of the present invention;

FIG. 3 illustrates a gap filling material comprising a magnetic filler and a binder material according to various embodiments of the present invention;

FIG. 4 illustrates magnetic filler showing a combination of particles within a gap filling material according to various embodiments of the present invention; and

FIGS. 5A, 5B and 5C illustrate cross sectional views of gap filling materials showing various embodiments of magnetic fillers according to various embodiments of the present invention.

### DETAILED DESCRIPTION OF THE INVENTION

As used herein, the term “electronic device” refers to one or more electronic components, and unless otherwise mentioned, the terms “electronic device” and “electronic component” have been used interchangeably throughout the specification. As used herein, “EM noise” and “RF noise” are used merely to refer to “electromagnetic (EM) radiation” emitted from an electronic device. Moreover, EM noise and RF noise, unless otherwise stated, have been used interchangeably throughout the specification.

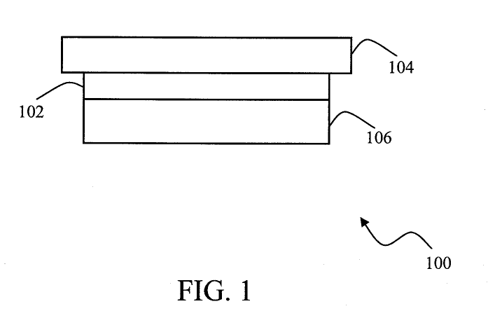

FIG. 1 illustrates an assembly 100 comprising a gap filling material 102 according to various embodiments of the present invention. The assembly 100 further comprises a heat dissipater 104 and an electronic device 106. The gap filling material 102 is a thermally conductive material. The gap filling material 102 also absorbs electromagnetic (EM) radiation. Specifically, the gap filling material 102 absorbs EM noise. EM noise refers to the unwanted EM radiation generated by an electronic device, such as the electronic device 106. Higher operating frequency ranges of the electronic device leads to the EM noise that primarily comprises radio frequency (RF) radiation. This RF radiation is normally referred to as RF noise. A non-exhaustive list of electronic devices 106 includes transmitters, transceivers, microcontrollers, and microprocessors, among others.

The electronic device 106 may comprise one or more components of various electronic instruments for example, LCDs, TFTs, plasma displays, laptops, high speed personal computers, video game consoles, mobile phones or the like. Besides emitting EM radiation, electronic device 106 produces heat when in operation. The heat dissipater 104 is placed above the electronic device 106 to dissipate the excessive heat to the surrounding environment. The heat dissipater 104 may be secured to the electronic device 106 using various securing means, such as mechanical fasteners, for example clips, screws, rivets, clamps nut and bolts, soldering, adhesive and the like. However, the surfaces of the heat dissipater 104 or the electronic device 106 are not perfectly smooth. Consequently, the interface of the heat dissipater 104 and the electronic device 106 may contain substantially smaller gaps (not shown in the figures). These smaller gaps are filled up by air. Since air is considerably thermally non-conductive, these smaller gaps impede the conduction of heat through the interface of the heat dissipater 104 and the electronic device 106.

According to an aspect of the invention, the gap filling material 102 is advantageously placed at the interface between the heat dissipater 104 and the electronic device 106. The gap filling material 102 increases the contact area of the heat dissipater 104 and the electronic device 106 by filling in the smaller gaps. The gap filling material 102 facilitates the thermal conduction across the interface of the heat dissipater 104 and the electronic device 106. The gap filling material 102 also absorbs at least a portion of EM noise generated by electronic device 106. Thus, the gap filling material 102 retards the emission of EM noise from electronic device 106. The gap filling material 102 may exist in various forms and configurations. A non-exhaustive list of such forms and configurations of the gap filling material 102 includes greases, adhesives, compounds, films, elastomeric tapes, sheets, pads and the like.

Further, according to various embodiments, the present invention comprises a means for removing air from the interface (not shown in the figures). The means for removing air may be selected from various types of embossments and through holes. Specifically, any of the gap filling material 102, the heat dissipater 104 and the electronic device 106 may comprise one or more grooves, one or more channels, a series of holes through the material, or a combination thereof. The air gap may be trapped at a first interface of the gap filling material 102 and the electronic device 106, or at a second interface of the gap filling material 102 and the heat dissipater 104, or at both the first and second interfaces. The grooves, channels, and holes help to expel any air trapped in both the first and second interfaces. Air can be expelled from the interfaces through grooves, channels, or holes, when pressure is applied at the first and second interfaces.

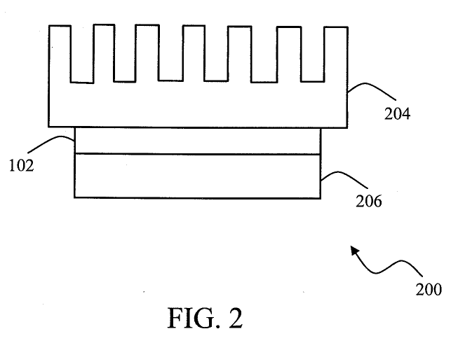

FIG. 2 illustrates an assembly 200 comprising the gap filling material 102 placed between a metal sub-chassis 204 and a microprocessor 206 according to various embodiments of the present invention. The metal sub-chassis 204 is placed over the microprocessor 206. The metal sub-chassis 204 may be secured to the microprocessor 206 using various securing means, for example, mechanical fasteners, adhesives and the like. The gap filling material 102 is placed between the metal sub-chassis 204 and the microprocessor 206. The gap filling material 102 facilitates thermal conduction across the interface of the metal sub-chassis 204 and the microprocessor 206. The gap filling material 102 also absorbs the EM noise generated by the microprocessor 206. Thus, the gap filling material 102 retards the emission of EM noise from the microprocessor 206, avoiding EM interference with nearby electronic devices.

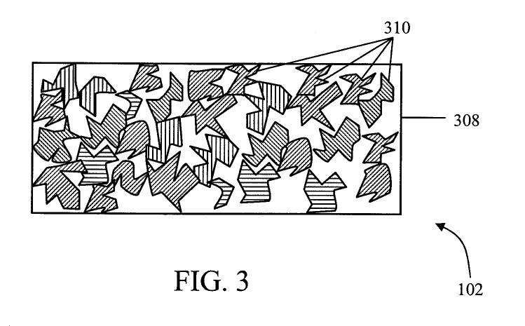

FIG. 3 illustrates a cross sectional view of the gap filling material 102 comprising a binder material 308 and magnetic filler 310 according to various embodiments of the present invention. The magnetic filler 310 is a powdered form of a magnetic material. Essentially, the magnetic filler 310 comprises particles of a magnetic material. The magnetic filler 310 can be dispersed into the binder material 308. The magnetic fillers 310 may have a substantially high thermal conductivity. The magnetic filler 310 dispersed into the binder material 308, provides thermal conductivity to the gap filling material 102. The excessive heat may be transferred through the gap filling material 102 by several means, for example, by molecular vibration of particles of the magnetic filler 310, by movement of high energy electrons across particles of the magnetic filler 310, among others. The gap filling material 102 transfers excessive heat through the magnetic filler 310 primarily by conduction.

Besides providing thermal conductivity, the gap filling material 102 absorbs EM noise generated by the electronic device 106 (as shown in FIG. 1). Gap filling material absorbs EM noise by means of magnetic coupling of magnetic field components of the EM noise with the magnetic filler 310. Absorption of EM noise by particles of the magnetic filler 310 is associated with the eddy currents, hysteresis and ferromagnetic resonance losses occurring in the particles of the magnetic filler. In certain embodiments of the present invention, the gap filling material may also be used to provide shielding to electronic devices against external EM radiations.

As will be apparent to one skilled in the art, the magnetic filler 310 may be obtained from various magnetic materials, composites, alloys or a mixture of like materials. A non-exhaustive list of magnetic materials, composites and alloys includes Iron (Fe), Nickel (Ni), Cobalt (Co), Ferrites, Alinco, Awaruite (Ni₃Fe), Wairauite (CoFe), MnBi, MnSb, CrO₂, MnAs, Gd or the like. The magnetic materials may also have various physical forms and chemical forms. Any of these various physical or chemical forms may be used to prepare the magnetic filler 310. An iron (Fe) based magnetic filler may, for example, include particles of a soft grade Carbonyl iron, a soft grade Carbonyl iron coated SiO₂ or FePO₄, Sendust FeAlSi, or Permalloy Fe—Ni and the like. In certain embodiments of the present invention, the magnetic filler 310 may comprise a mixture of magnetic particles from various magnetic materials.

Generally, the magnetic filler 310 imparts thermal conductivity to gap filling material 102. However, to further increase the thermal conductivity of the gap filling material 102, fillers of materials with high thermal conductivity may be dispersed in the binder material 308. These fillers may be obtained from a magnetic material, a non-magnetic material or a mixture thereof. A non-exhaustive list of non-magnetic thermal conductive materials includes aluminum, copper, silicon carbide, titanium diboride and the like.

According to certain embodiments of the present invention, the binder material 308 may be constructed from various materials depending on the form of the gap filling material 102. A non-exhaustive list of various forms of the gap filling material 102 includes greases, adhesives, compounds, films, elastomeric tapes, sheets, pads or the like. As will be apparent to one skilled in the art, the binder material 308 may include, for example, silicone elastomers, thermoplastic rubbers, urethanes, acrylics and the like. Silicone elastomers are constructed from silicone gums crosslinked using a catalyst. Thermoplastic rubbers are typically thermoplastic blockpolymers for example, a styrene-ethylene-butylene-styrene block copolymer having a styrene/rubber ratio of 13/87.

Alternatively, thermoplastics, such as crosslinked block copolymers of styrene/olefin polymers with suitable functional groups, for example, carboxyl groups, ethoxysilanol groups, and the like. In order to form a crosslink, a crosslinking agent and a crosslinking catalyst are combined with the crosslinkable copolymer. In certain embodiments of the present invention, where the gap filling material 102 is in the form of a film, the binder material 308 can include polyolefins, such as polyethylene, polyimides, polyamides, polyesters and the like. These films have poor thermal conductivities, and the addition of thermal conductive filler, such as titanium diboroide, boron nitride, aluminum oxide, or the like, or a mixture thereof, improves the thermal properties of the film.

In certain embodiments of the present invention, where the gap filling material 102 is in the form of a tape or an adhesive, the binder material 308 can be a pressure sensitive adhesive material, such as a silicone, urethane or an acrylic adhesive resin.

Further, in certain embodiments of the present invention, where the gap filling material 102 is in the form of a grease, the binder material 308 can be uncrosslinked silicone. In the elastomeric or tape configuration, one or more layers of conductive support materials may be incorporated into the binder material 308 to increase the toughness, resistance to elongation, and resistance to tearing of the gap filling material 102. A non-exhaustive list of supporting materials includes synthetic and non-synthetic fibers such as, glass fiber, glass mesh, glass cloth, plastic fiber, plastic mesh, plastic cloth, plastic films, metal fiber, metal mesh, metal cloth, metal foils and the like. Some of the supporting materials are thermally conductive and others are thermally non-conductive. As will be apparent to one skilled in the art, one or more types of thermal conductive fillers may be added to a thermally non-conductive supporting material to make it thermally conductive.

FIG. 3 illustrates a cross sectional view of the gap filling material 102 showing the magnetic filler 310 as flakes according to various embodiments of the present invention. Particles are obtained in the form of flakes from the magnetic materials. The magnetic filler 310, in the form of the flakes, is dispersed into the binder material 308 to form the gap filling material 102.

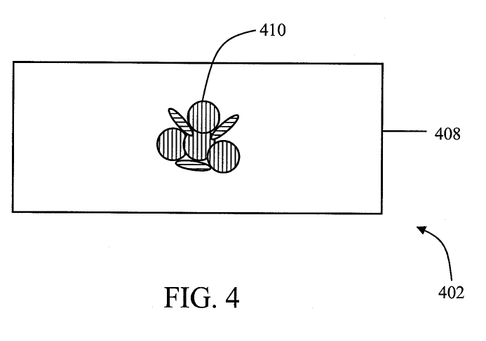

FIG. 4 illustrates the magnetic filler 410 showing combination of particles within the gap filling material 402 according to various embodiments of the present invention. It is usually desired to disperse the magnetic filler 410 in the binder material 408 in such a way that the resulting the gap filling material 402 is homogeneous, and to avoid any lump formation of the magnetic filler 410. As will be apparent to one skilled in the art, the magnetic filler 410 may be dispersed into the binder material 408 using various methods, for example, mechanical in-line disperser method, spinning wheel methods, dropping methods, or the like.

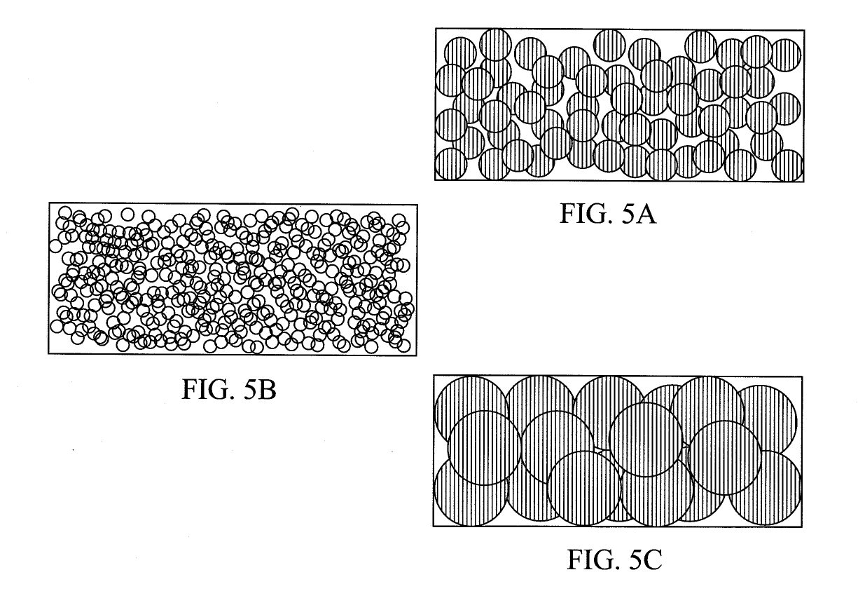

FIGS. 5A, 5B and 5C illustrate cross sectional views of gap filling materials showing various embodiments of the magnetic filler according to various embodiments of the present invention.

FIG. 5A illustrates a cross sectional view of the gap filling material comprising spherical shape wafers of the magnetic filler. In certain embodiments of the present invention, the magnetic filler comprises particles having circular wafers.

FIG. 5B illustrates a cross sectional view of the gap filling material comprising magnetic fillers with smaller particle sizes. The particle size of the magnetic filler may range from about sub-microns to about several millimeters. Moreover, magnetic fillers with smaller particle sizes are shown with spherical particle shapes. However, it will be apparent to one skilled in the art that the magnetic filler may comprise particles having various shapes, for example, regular or irregular flakes, grains, cubes, oblongs or the like.

FIG. 5C illustrates a cross sectional view of a gap filling material comprising a magnetic filler with larger particle sizes.

Each of the gap filling materials shown in FIGS. 5A, 5B and 5C comprises a different embodiment of the magnetic filler. In certain embodiments, the gap filling material may contain a mixture of the various embodiments of the magnetic filler in terms of shapes and sizes of the particles.

According to various embodiments, the present invention may be used as a method to provide a gap filling material as discussed previously. The method includes providing a binder material and dispersing at least one magnetic filler into the binder material. The method may be used for conducting heat across an interface of a first surface and a second surface. The method may also be used for absorbing EM radiation emitted from the first surface and/or the second surface. The method includes providing a binder material and dispersing at least one magnetic filler into the binder material thereby forming a gap filling material. The method further includes placing the gap filling material in the interface. The gap filling material provides conduction of the excessive heat generated by an electronic device. At the same time, the gap filling material retards emission of EM noise emitted from the electronic device.

Among other advantages that will be apparent to those skilled in the art, the gap filling material provides a thermal conduction at the interface between the heat dissipater and the electronic device, and at the same time, absorbs EM noise emitted by the electronic device. Further, the gap filling material is available for use in many convenient forms, such as greases, adhesives, compounds, films, elastomeric tapes, sheets, pads and the like depending upon the particular application and requirements. Furthermore, the gap filling material is also usable for the shielding of electronic devices. Yet furthermore, the gap filling material is easy to manufacture and cost effective.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is intended to cover all modifications, equivalents, and alternatives falling within the spirit and scope of the invention as defined by the following appended claims.

What is claimed is:

1. A gap filling material for the absorption of electromagnetic (EM) radiation, the gap filling material being thermally conductive, the gap filling material comprising:
a binder material; and
at least one magnetic filler being dispersed in the binder material.

2. The gap filling material of claim 1, wherein the gap filling material is in the form of a grease.

3. The gap filling material of claim 1, wherein the gap filling material is in the form of a cream.

4. The gap filling material of claim 1, wherein the gap filling material is in the form of a sheet.

5. The gap filling material of claim 1, wherein the gap filling material is in the form of a tape.

6. The gap filling material of claim 5, wherein the tape comprises at least one groove, each of the at least one groove being cut on the tape.

7. The gap filling material of claim 5, wherein the tape comprises at least one channel, each of the at least one channel being cut on the tape.

8. The gap filling material of claim 5, wherein the tape comprises at least one hole, each of the at least one hole being cut on the tape.

9. The gap filling material of claim 1, wherein the gap filling material further comprises a thermal conductive filler, the thermal conductive filler being non-magnetic, the thermal conductive filler being dispersed in the binder material.

10. The gap filling material of claim 9, wherein the thermal conductive filler is chosen from the group of materials consisting of aluminum, copper and titanium diboride.

11. The gap filling material of claim 1, wherein the binder material is chosen from the group of materials consisting of silicone binder, thermoplastic rubber binder, urethane, polyolefin, and pressure sensitive adhesive material.

12. The gap filling material of claim 1, wherein the at least one magnetic filler comprises iron particles.

13. The gap filling material of claim 1, wherein the at least one magnetic filler is chosen from a group of magnetic materials consisting of nickel, cobalt, permalloy Fe—Ni, carbonyl iron, carbonyl iron coated with SiO₂, and carbonyl iron coated with FePO₄.

14. The gap filling material of claim 1, wherein the particles of magnetic filler have a shape selected from a group of shapes consisting of regular or irregular flakes, spheres, circular wafers, and cubes.

15. The gap filling material of claim 1, wherein the size of the magnetic filler ranges from about 1 micron to about 1 mm.

16. A method for providing a gap filling material for the absorption of electromagnetic (EM) radiation, the gap filling material being thermally conductive, the method comprising:
providing a binder material; and
dispersing at least one magnetic filler in the binder material.

17. The method of claim 16 further comprising the step of dispersing at least one non-magnetic filler in the binder material, wherein the at least one non-magnetic filler is a thermal conductive filler.

18. A method for conducting heat across an interface and for absorbing electromagnetic (EM) radiation, the method comprising:
providing a binder material;
dispersing at least one magnetic filler in the binder material thereby forming a gap filling material; and
placing the gap filling material in the interface.

19. A method of conducting heat across the interface of an electronic device and a heat dissipater, the heat dissipater being placed over the electronic device, the method being used for the absorption of electromagnetic (EM) radiation emitted by the electronic device, the method comprising:
providing a binder material;
dispersing at least one magnetic filler in the binder material thereby forming a gap filling material; and
placing the gap filling material in the interface.
